(19) United States
(12) Patent Application Publication
(10) Pub. No.: US 2026/0106433 A1
(43) Pub. Date: Apr. 16, 2026

(54) LIGHT EMITTING DEVICE AND LIGHT EMITTING MODULE

(71) Applicant: NICHIA CORPORATION, Anan-shi, Tokushima (JP)

(72) Inventors: Kiyoshi ENOMOTO, Tokushima-shi (JP); Yuto GODA, Anan-shi (JP)

(21) Appl. No.: 19/358,989

(22) Filed: Oct. 15, 2025

(30) Foreign Application Priority Data
Jun. 9, 2025 (JP) 2025-095419
Oct. 16, 2024 (JP) 2024-180835

(51) Int. Cl. H01S 5/042; G03B 21/20; H01S 5/023; H01S 5/40

(52) U.S. Cl. CPC H01S 5/04256; G03B 21/2013; G03B 21/2033; H01S 5/023; H01S 5/4093

(57) ABSTRACT

A light emitting device includes a first light emitting element, second light emitting elements, and third light emitting elements, a base including first to fourth wiring parts, and wires. The first, second, and third wiring parts is connected to one of the two electrodes of the first, second and third light emitting elements, respectively. The fourth wiring part is connected to the other of the two electrodes. A first current path is formed between the first wiring part and the fourth wiring part to be taken by the first light emitting element. A second current path is formed between the second wiring part and the fourth wiring part to be taken by the second light emitting elements. A third current path is formed between the third wiring part and the fourth wiring part to be taken by the third light emitting elements.

### CROSS-REFERENCE TO RELATED APPLICATION

This application is based on and claims priority to Japanese Patent Application No. 2024-180835, filed on October 16, 2024, and Japanese Patent Application No. 2025-095419, filed on June 9, 2025. The entire contents of these applications are incorporated herein by reference.

### TECHNICAL FIELD

The present disclosure relates to a light emitting device and a light emitting module.

### BACKGROUND

Japanese Patent Publication No. 2022-145467 discloses a light emitting device in which a red light emitting element, a blue light emitting element, and a green light emitting element are disposed on the mounting face of a base, and the light emitting elements are electrically connected to the base by using a plurality of wires.

### SUMMARY

The present disclosure enables an achievement of a high output light emitting device with high manufacturing stability.

The present disclosure enables an achievement of size reduction of a light emitting device in place of the object described above.

The present disclosure enables an achievement of increase in the output of a light emitting device in place of the objects described above.

In the present specification, a disclosure capable of achieving the objectives described above compositely is also disclosed.

A light emitting device according to an embodiment includes a plurality of light emitting elements including a first light emitting element, a plurality of second light emitting elements, and a plurality of third light emitting elements, each of the plurality of light emitting elements including two electrodes that are an anode electrode and a cathode electrode; a base including a first wiring part, a second wiring part, a second wiring part, a third wiring part, a fourth wiring part, and a mounting face provided between two of the first wiring part, the second wiring part, the third wiring part, and the fourth wiring part in a plan view; and a plurality of wires electrically connecting the plurality of light emitting elements to the base. In the plan view, the plurality of light emitting elements are disposed on the mounting face with the first light emitting element being arranged between the plurality of second light emitting elements and the plurality of third light emitting elements. The first wiring part is electrically connected to one of the two electrodes of the first light emitting element. The second wiring part is electrically connected to one of the two electrodes of each of the plurality of second light emitting elements. The third wiring part is electrically connected to one of the two electrodes of each of the plurality of third light emitting elements. The fourth wiring part is electrically connected to the other of the two electrodes of the first light emitting element, the other of the two electrodes of each of the plurality of second light emitting elements, and the other of the two electrodes of each of the plurality of third light emitting elements. A first current path is formed between the first wiring part and the fourth wiring part to be taken by the first light emitting element and not taken by any of the plurality of second light emitting elements and the plurality of third light emitting elements. A second current path is formed between the second wiring part and the fourth wiring part to be taken by the plurality of second light emitting elements and not taken by any of the first light emitting element and the plurality of third light emitting elements. A third current path is formed between the third wiring part and the fourth wiring part to be taken by the plurality of third light emitting elements and not taken by any of the first light emitting element and the plurality of second light emitting elements.

A light emitting module disclosed by an embodiment includes any one of the light emitting devices described above and a wiring board on which the light emitting device is mounted.

At least one of disclosures disclosed by the embodiments can provide a high output light emitting device with high manufacturing stability.

### BRIEF DESCRIPTION OF THE DRAWINGS

FIG. 1 is a perspective view of a light emitting device according to first and second embodiments.

FIG. 2 is a top view of the light emitting device according to the first and second embodiments.

FIG. 3 is a cross-sectional view of the light emitting device according to the first and second embodiments taken along line III-III in FIG. 2.

FIG. 4 is a perspective view showing the internal structure of a package of the light emitting device according to the first embodiment.

FIG. 5 is a top view showing the internal structure of the package of the light emitting device according to the first embodiment.

FIG. 6 is a top view showing a wiring connection form of a light emitting device according to the first embodiment.

FIG. 7 is a top view of a package according to the first and second embodiments.

FIG. 8 is a cross-sectional view of the package according to the first and second embodiments taken along line VIII-VIII in FIG. 7.

FIG. 9 is a cross-sectional view of a base corresponding to the cross-sectional view of the package in FIG. 8.

FIG. 10 is a top view of a base according to the first and second embodiments.

FIG. 11 is a bottom view of the base according to the first and second embodiments.

FIG. 12 is a top view showing a submount according to the first and second embodiments on which a light emitting element and a protective element are mounted.

FIG. 13 is a side view showing the submount according to the first and second embodiments on which the light emitting elements and the protective element are mounted.

FIG. 14A is a top view of a light emitting device provided as a comparison to the light emitting device according to the first and second embodiments.

FIG. 14B is a top view showing a wiring connection form in the light emitting device provided as a comparison to the light emitting device according to the first and second embodiments.

FIG. 15 is a top view showing a wiring connection form in a light emitting device according to the second embodiment.

FIG. 16 is a perspective view of a light emitting module according to a third embodiment.

FIG. 17 is a top view of the light emitting module according to the third embodiment.

FIG. 18 is a top view of a wiring board according to the third embodiment.

### DETAILED DESCRIPTION

In the present specification and the scope of claims, a polygon, such as a triangle, rectangle, or the like, includes a shape subjected to processing, such as cutting angles, chamfering, beveling, rounding, or the like. Moreover, the location of such processing is not limited to a corner (an end of a side) of a polygon. Rather, a shape subjected to processing in the intermediate portion of a side will similarly be referred to as a polygon. In other words, any polygon-based shape subjected to partial processing should be understood to be included in the interpretation of a “polygon” disclosed in the present specification and the scope of claims.

This similarly applies to any word describing a specific shape, such as a trapezoidal, circular, recessed, or projected shape, without being limited to a polygon. This also similarly applies to the sides defining such shapes. In other words, even if a corner or intermediate portion of a side is subjected to processing, the term “side” should be interpreted to include the processed portion. To distinguish a “polygon” or “side” that is intentionally not processed from a shape subjected to processing, the shape will be described by adding the phrase “exact,” such as “an exact rectangle.”

In the description or the scope of claims, terms, such as up/down, above/below, upward/downward, left/right, front/back, front/rear, forward/rearward, in front/in the back, and the like merely describe a relationship between relative positions, directions, or orientations. Such a relationship does not have to match the relationship in actual use. The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

In the drawings, directions such as the X direction, the Y direction, and the Z direction might occasionally be indicated by arrows. These arrowed directions are consistent among multiple drawings related to the same embodiment. The directions pointed by the X, Y, and Z arrows are positive directions, and the opposite directions to these are negative directions. For example, the direction indicated as X in front of the arrow is the X direction and positive direction. In the present specification, the direction that is X direction and positive direction is referred to as the “positive X direction,” and the direction opposite thereto is referred to as the “negative X direction.” The “X direction” includes both the positive and negative directions. The same applies to the Y and Z directions.

In the present specification, when describing a certain subject identified as being “one or plural,” both an embodiment having a single subject and an embodiment having plural subjects are collectively described. Accordingly, a description which identifies the subject as “one or plural” supports any of the cases in which an embodiment includes one or plural subjects, at least one subject, and plural subjects.

In the present specification, a description regarding “one or each” subject collectively describes cases in which an embodiment having a single subject and the single subject is described, an embodiment having plural subjects and one of the plural subjects is described, and an embodiment having plural subjects and each of the plural subjects is described. Accordingly, a description regarding “one or each” subject supports any of embodiments in which at least one subject is included and the description applies to the one subject, plural subjects are included and the description applies to at least one of the plural subjects, and plural subjects are included and the description applies to each of the plural subjects.

In the present specification, terms such as “member” and “part/portion” are used to describe a constituent element, for example. The term “member” refers to a subject that is treated as a single physical unit. A subject treated as a single physical unit can be considered as a component in the manufacturing process. The term “part/portion” refers to a subject that does not have to be treated as a single physical unit. The term “part/portion” is used, for example, to capture one part of a member, capture multiple members collectively as one subject, or the like.

A distinction made between the “member” and the “part/portion” described above is not intended to consciously limit the scope of the right in the interpretation of the doctrine of equivalence. In other words, even if there is a constituent element in the scope of claims disclosed as a “member,” the applicant does not recognize it essential to treat the constituent element as a single physical unit in order to apply the present disclosure.

In the present specification and the scope of claims, when there are multiple pieces of elements having the same designation and a distinction must be made, a word such as “first,” “second,” or the like might occasionally be added to the designation. There might be an occasion where the element designation with the same distinguishing word in the scope of claim and the description do not refer to the same element. For this reason, even if there are constituent elements recited in the scope of claims having the same distinguishing words as in the present specification, it is possible that the subjects identified by them do not match between the present specification and the scope of claims.

For example, in the case in which there are elements that are distinguished by the words, “first,” “second,” and “third,” in the present specification, and only the “first” and “third” elements are recited in a certain claim, they might be distinguished by the words, “first” and “second,” in the claim for readability. In such a case, the elements accompanied by the words, “first” and “second,” in the claim would refer to the subjects accompanied by the words, “first” and third” in the description. This rule applies to not only constituent elements, but also other subjects in a reasonable and flexible manner.

Certain embodiments of the present disclosure will be explained below. Specific forms for implementing the present disclosure will be described with reference to the accompanying drawings. Forms for implementing the present disclosure are not limited to these specific forms. In other words, these embodiments illustrated are not the only forms for realizing the present disclosure. The sizes of and relative positions of the members illustrated might be exaggerated for clarity of explanation.

### First Embodiment

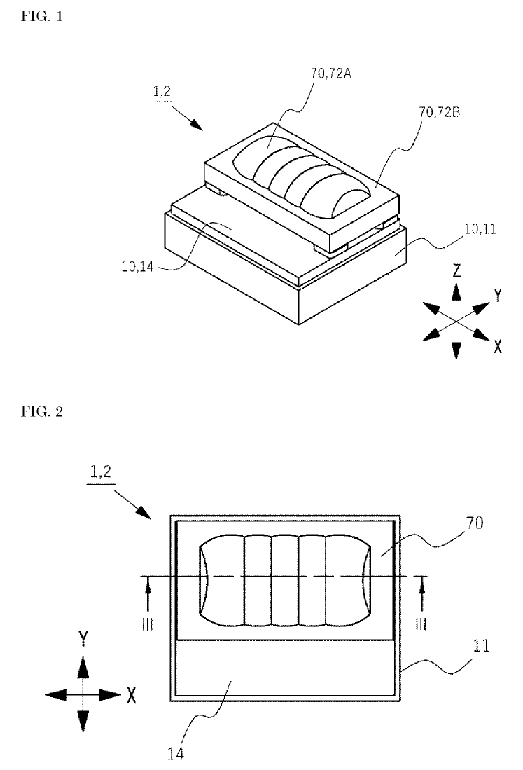

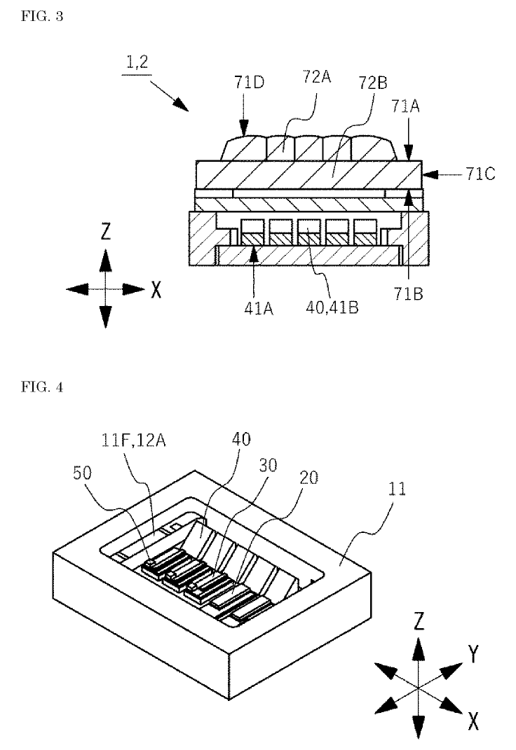

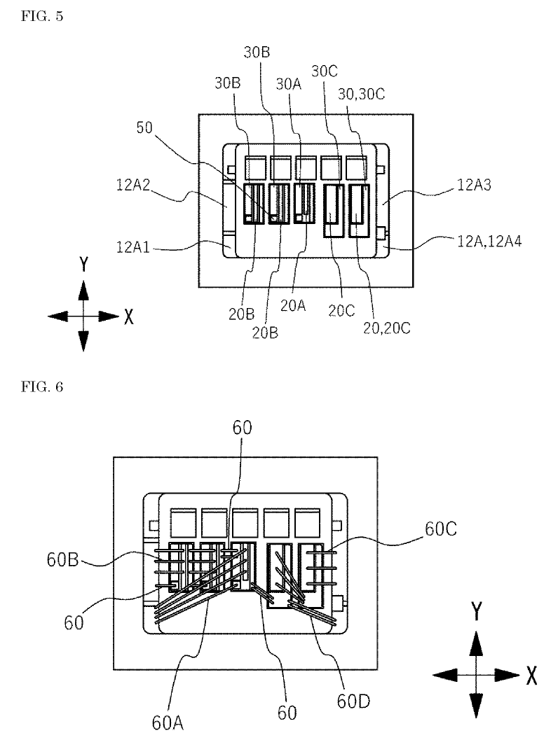

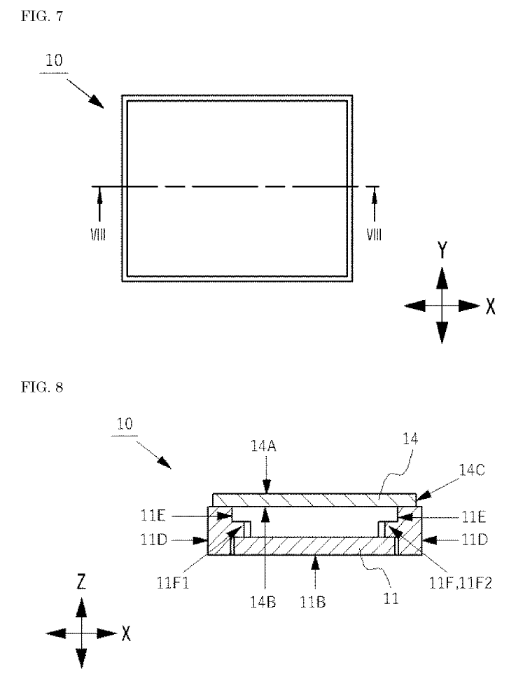

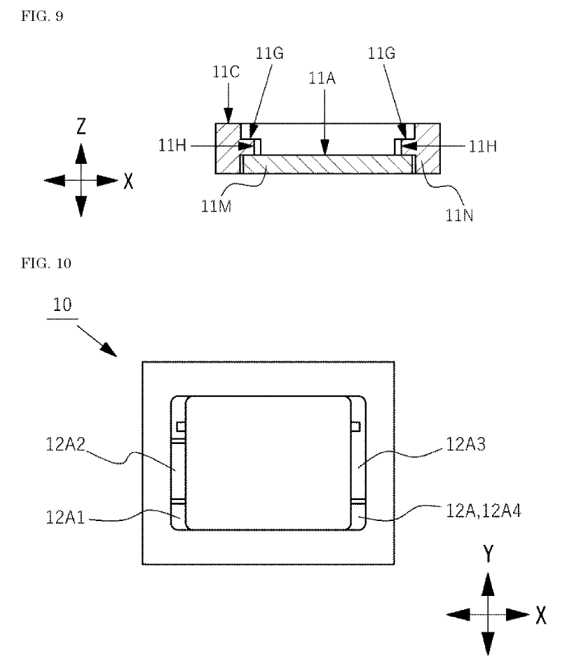

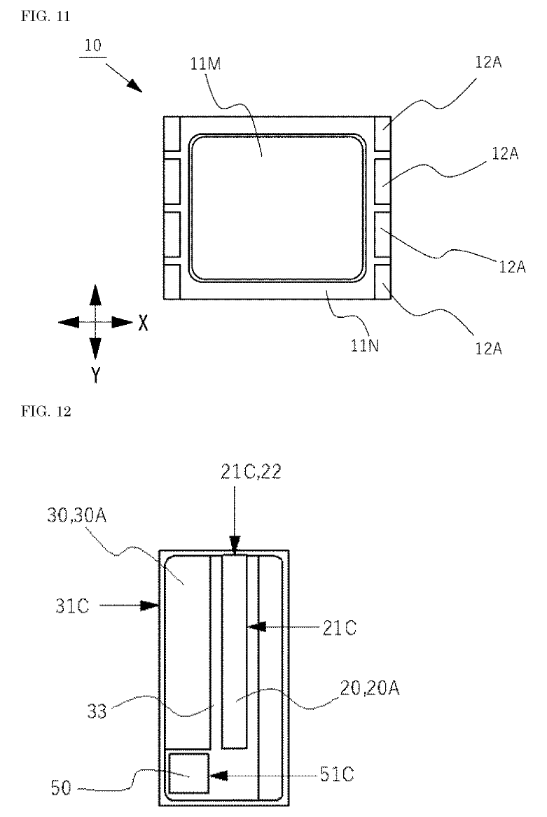

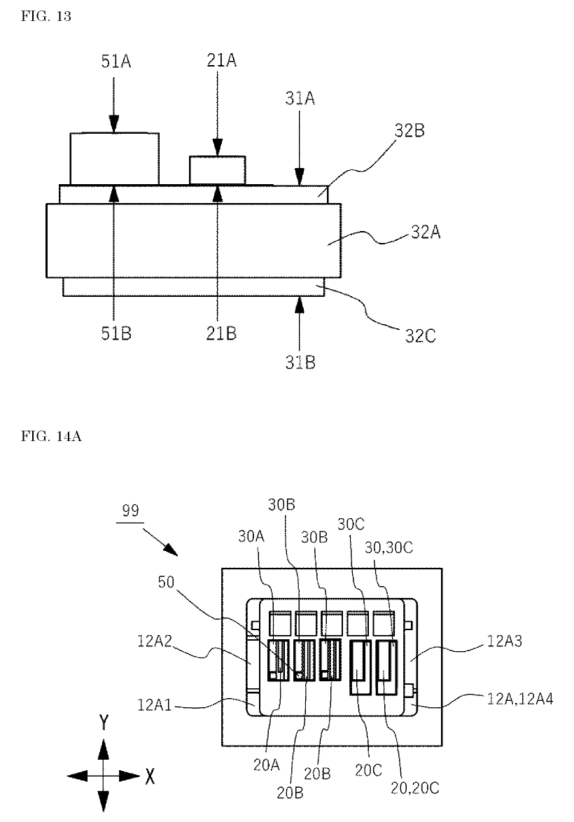

A light emitting device 1 according to a first embodiment will be explained. FIGS. 1 to 13 are drawings explaining an exemplary form of light emitting device 1. FIG. 1 is a perspective view of the light emitting device 1. FIG. 2 is a top view of the light emitting device 1. FIG. 3 is a cross-sectional view of the light emitting device 1 taken along line III-III in FIG. 2. FIG. 4 is a perspective view showing the internal structure of a package 10 of the light emitting device 1. FIG. 5 is a top view showing the internal structure of the package 10 of the light emitting device 1. FIG. 6 is a top view showing how wires 60 are connected in the light emitting device 1. FIG. 7 is a top view of the package 10. FIG. 8 is a cross-sectional view of the package 10 taken along line VIII-VIII in FIG. 7. FIG. 9 is a cross-sectional view of a base 11 corresponding to the cross-sectional view of the package 10 in FIG. 8. FIG. 10 is a top view of the base 11. FIG. 11 is a bottom view of the base 11. FIG. 12 is a top view showing a submount 30 on which a light emitting element 20 and a protective element 50 are mounted. FIG. 13 is a side view of the submount 30 on which the light emitting element 20 and the protective element 50 are mounted.

A light emitting device 1 includes a plurality of constituent elements. These constituent elements include a package 10, plural light emitting elements 20, one or plural submounts 30, one or plural reflecting members 30, one or plural protective elements 50, plural wires 60, and an optical member 70.

A light emitting device 1 may include other constituent elements besides those described above. For example, the light emitting device 1 may include an additional light emitting element 20 besides the one or plural light emitting elements 20. A light emitting device 1 may exclude some of the constituent elements listed above.

Each constituent element will be explained.

### Package 10

A package 10 includes a base 11 and a lid 14. The package 10 is formed by bonding the lid 14 to the base 11. In the package 10, an internal space is defined in which other constituent elements are disposed. The internal space is a closed space enclosed by the base 11 and the lid 14. The internal space can be a vacuum or airtight sealed space.

In a top view, the outline of the package 10 is quadrangular. The quadrangular shape can have short sides and long sides. In the package 10 shown in the drawings, the long side direction of the quadrangular shape coincides with the X direction, and the short side direction coincides with the Y direction. In a top view, the outline of the package 10 does not have to be quadrangular.

In the package 10, an internal space where other constituent elements are disposed is formed. The upper face 11A of the package 10 is a part of the regions that define the internal space. Each lateral face 11E and the lower face 14B of the package 10 are parts of the regions that define the internal space.

A base 11 has a first upper face 11A and a lower face 11B. The base 11 has a second upper face 11C. The base 11 has one or plural outer lateral faces 11D. The base 11 has one or plural inner lateral faces 11E. The one or plural outer lateral faces 11D intersect the second upper face 11C. The one or plural outer lateral faces 11D intersect the lower face 11B. The one or plural inner lateral faces 11E intersect the second upper face 11C.

In a top view, the outline of the base 11 is quadrangular. In a top view, the outline of the base 11 constitutes the outline of the package 10. In a top view, the outline of the first upper face 11A is quadrangular. This rectangular shape can have long sides and short sides. The long side direction of the first upper face 11A is parallel to the long side direction of the outline of the base 11. In a top view, the outline of the first upper face 11A does not have to be quadrangular.

In a top view, the first upper face 11A is surrounded by the second upper face 11C. The second upper face 11C is an annular face that surrounds the first upper face 11A in a top view. The second upper face 11C is a rectangular annulus. Here, the frame defined by the inner edges of the second upper face 11C will be referred to as the inner frame of the second upper face 11C, and the frame defined by the outer edges of the second upper face 11C will be referred to as the outer frame of the second upper face 11C.

The base 11 has a recess surrounded by the frame made by the second upper face 11C. The recess defines a portion that is depressed downward from the second upper face 11C. The first upper face 11A is a part of the recess. Th one or plural inner lateral faces 11E are parts of the recess. The second upper face 11C is positioned higher than the first upper face 11A.

The base 11 has one or plural stepped portions 11F. A stepped portion 11F has an upper face 11G, and a lateral face 11H that intersects the upper face 11G and extends from the upper face 11G downwards. Here, a stepped portion 11F only has one upper face 11G and one lateral face 11H. The upper face 11G intersects the inner lateral face 11E. The lateral face 11H intersects the first upper face 11A.

The stepped portion 11F or each stepped portion 11F is disposed inward of the inner frame of the second upper face 11C in a top view. The stepped portion 11F or each stepped portion 11F is formed along the inner lateral face 11E in part or whole in a top view. In the base 11, the lateral face 11H is an inner lateral face, but the lateral face 11H and the inner lateral face 11E are different faces. The inner lateral face 11E or each inner lateral ace 11E and the lateral face 11H or each lateral face 11H are perpendicular to the first upper face 11A. Here, being perpendicular tolerates an error of up to ±3 degrees.

The one or plural stepped portions 11F can include a first stepped portion 11F1 and a second stepped portion 11F2. The first stepped portion 11F1 and the second stepped portion 11F2 are disposed at positions such that their lateral faces 11F oppose one another. The first stepped portion 11F1 and the second stepped portion 11F2 are disposed along the short-length sides of the inner frame of the second upper face 11C.

The base 11 has a base part 11M and a frame part 11N. The base part 11M and the frame part 11N may be members made of different materials. The base 11 can be composed of a base member corresponding to the base part 11M and a frame member corresponding to the frame part 11N.

The base part 11M includes the first upper face 11A. The frame part 11N includes the second upper face 11C. The frame part 11N includes one or plural outer lateral faces 11D and one or plural inner lateral faces 11E. The frame part 11N includes one or plural stepped portions 11F.

The lower face of the base part 11M constitutes a portion of or the entire region of the lower face 11B of the base 11. In the case in which the lower face of the base part 11M constitutes a portion of the lower face 11B of the base 11, the lower face of the frame part 11N constitutes the remaining region of the lower face 11B of the base.

The base 11 has plural wiring parts 12A. The wiring parts 12A include one or plural wiring parts 12A disposed in the internal space of the package 10 (inner wiring parts) and one or plural wiring parts 12A disposed on the outer surface of the package 10 (outer wiring parts).

The inner wiring part or each inner wiring part is disposed on the upper face 11G of a stepped portion 11F. The base 11 has one or plural inner wiring parts disposed on the upper face 11G of the first stepped portion 11F1. The base 11 has one or plural inner wiring parts disposed on the upper face 11G of the second stepped portion 11F2.

The wiring parts 12A include a first wiring part 12A1, a second wiring part 12A2, a third wiring part 12A3, and a fourth wiring part 12A4. The first wiring part 12A1, the second wiring part 12A2, the third wiring part 12A3, and the fourth wiring part 12A4 are all inner wiring parts. All of the first wiring part 12A1, the second wiring part 12A2, the third wiring part 12A3, and the fourth wiring part 12A4 are disposed on the upper face 11G of the one or plural stepped portions 11F.

The first wiring part 12A1 and the second wiring part 12A2 are disposed in one direction. The first wiring part 12A1 and the second wiring part 12A2 are disposed on the upper face 11G of the first stepped portion 11F1. In the light emitting device 1 shown in the drawings, the direction in which the first wiring part 12A1 and the second wiring part 12A2 are arranged coincides with the Y direction.

The third wiring part 12A3 and the fourth wiring part 12A4 are arranged in one direction. The third wiring part 12A3 and the fourth wiring part 12A4 are disposed on the upper face 11G of the second stepped portion 11F2. In the light emitting device 1 illustrated, the direction in which the third wiring part 12A3 and the fourth wiring part 12A4 are arranged coincides with the Y direction.

In a top view, the first upper face 11A is located between the first stepped portion 11F1 and the second stepped portion 11F2. It can be said that, in a top view, the first upper face 11A is located between two of the first wiring part 12A1, the second wiring part 12A2, the third wiring part 12A3, and the fourth wiring part 12A4. It can be said that the first upper face 11A is located between a pair of the wiring parts in which the first and second wiring parts 12A1 and 12A2 disposed in one direction and another pair of the wiring parts in which the third and fourth wiring parts 12A3 and 12A4 disposed in one direction.

The outer wiring part or each outer wiring part is disposed on the lower face 11B of the package 10. The outer wiring part or each outer wiring part is disposed on the lower face of the frame part 11N. The outer wiring part(s) may be disposed on an outer surface that is different from the lower face 11B of the package 10.

In the base 11, the inner wiring part or each inner wiring part is electrically connected to the outer wiring part(s). The one or plural inner wiring parts are electrically connected to the outer wiring parts that are different from one another.

The base 11 can be formed, for example, by using a ceramic as a primary material. Examples of ceramics for use as a primary material for the base 11 include aluminum nitride, silicon nitride, aluminum oxide, or silicon carbide.

Here, a primary material is a material occupying the largest portion in mass or volume of a subject formed body. In the case in which a subject formed body is made of a single material, the material is the primary material. In other words, a given material being a primary material of a subject includes the case in which the material constitutes 100% of the subject.

The base 11 may be formed with a base member and a frame member that are formed of primary materials that are different from one another. The base member can be formed, for example, by using a material that excels in heat dissipation, such as a metal, a composite containing a metal, graphite, diamond, or the like. A metal for use as a primary material for the base member is, for example, copper, aluminum, or iron. A composite containing a metal for use as a primary material for the base member is, for example, molybdenum copper or tungsten copper. The frame member can be formed by using as a primary material any of the ceramics listed as a primary material for the base 11 described above.

The wiring parts 12A can be formed, for example, by using a metal as a primary material. Examples of metal materials for use as a primary material for the wiring parts 12A include simple metals, such as Cu, Ag, Ni, Au, Ti, Pt, Pd, Cr, W, and the like, or alloys containing these metals. The wiring parts 12A may include one or plural metal layers, for example.

A lid 14 has an upper face 14A and a lower face 14B. The lid 14 further has one or plural lateral faces 14C. The lid 14 is a cuboid having a flat sheet shape. The lid 14 does not have to be a cuboid.

The lid 14 is bonded to the base 11. The lower face 14B of the lid 14 is bonded to the second upper face 11C of the base 11. The lid 14 is bonded to the base 11 via an adhesive.

The lid 14 has light transmissivity to allow light to pass through. Here, light transmissivity means a light transmittance of 80% or higher for the light that becomes incident on the lid 14. The lid 14 may have a non-transmissive region (region not having light transmissivity) in part.

The lid 14 can be formed by using glass as a primary material. Not limited to glass, the lid 14 may be formed by using, for example, sapphire as a primary material.

### Light Emitting Element 20

A light emitting element 20 has an upper face 21A, a lower face 21B, and lateral faces 21C. The shape of the upper face 21A is quadrangular. This quadrangular shape has long sides and short sides. In a top view, the outline of the light emitting element 20 is quadrangular. This quadrangular shape has long sides and short sides. The shape of the upper face 21A and the top view outline of the light emitting element 20 are not limited to this.

A light emitting element 20 has a light emission face 22 through which light is output. For example, one of the lateral faces 21C can be a light emission face 22. The lateral face 21C which serves as the light emission face 22 intersects a short side of the upper face 21A. Moreover, for example, the upper face 21A can be a light emission face 22. The light emitting element 20 has one or plural light emission faces 22.

A light emitting element 20 has two electrodes, an anode and a cathode. The two electrodes can be individually disposed on two opposing faces. For example, one of the two electrodes is disposed on the upper face 21A, and the other electrode on the lower face 21B. Both electrodes may be disposed on one face.

For a light emitting element 20, for example, a blue light emitting element can be employed. For example, for a light emitting element 20, a green light emitting element can be employed. For example, for a light emitting element 20, a red light emitting element can be employed. For a light emitting element 20, one that emits light of another color or wavelength may be employed.

Here, blue light refers to light whose peak wavelength falls within a 420 nm to 494 nm range. Green light refers to light whose peak wavelength falls within a 495 nm to 570 nm range. Red light refers to light whose peak wavelength falls within a 605 nm to 750 nm range.

Examples of light emitting elements 20 that emit blue or green light include light emitting elements that include nitride semiconductors. For the nitride semiconductors, for example, GaN-based semiconductors, such as GaN, InGaN, AlGaN, or the like can be employed. Examples of light emitting elements 20 that emit red light include those that include InAlGaP-based semiconductors, GaInP-based semiconductors, or GaAs-based semiconductors, such as GaAs, AlGaAs, or the like.

For a light emitting element 20, for example, a semiconductor laser element can be employed. For the light emitting element 20, a single emitter semiconductor laser element having a single emitter can be employed. For the light emitting element 20, a multi-emitter semiconductor laser element having multiple emitters can be employed. Not limited to a semiconductor laser element, a light emitting diode or the like may be employed for the light emitting element 20.

Here, as one example of light emitting element 20, a semiconductor laser element will be described.

A semiconductor laser element emits laser light which has directivity. Divergent light that spreads is emitted from the light emission face 22 of a semiconductor laser element. The light emitted from a semiconductor laser element forms an elliptical far field pattern (hereinafter referred to as “FFP”) in a plane parallel to the light emission face 22. An FFP represents the shape and the light intensity distribution of the emitted light at a position that is distant from the light emission face of a semiconductor laser element.

The light passing the center of the elliptical FFP, in other words, the light having the peak intensity in the light intensity distribution of the FFP will be referred to as the light advancing or travelling along the optical axis. The light having an intensity of at least 1/e² relative to the peak intensity value in the light intensity distribution of an FFP will be referred to as the “main portion” of the light.

The shape of an FFP of the light emitted from a semiconductor laser element in a plane parallel to the light emission face 22 is elliptical which is longer in the stacking direction than the direction perpendicular to the stacking direction. The stacking direction refers to the direction in which semiconductor layers including an active layer are stacked in the semiconductor laser element. The direction perpendicular to the stacking direction in other words is the planar direction of the semiconductor layers. The major axis direction of the elliptical shape of an FFP can also be referred to as the fast axis direction of the semiconductor laser element and the minor axis direction the slow axis direction of the semiconductor laser element.

Based on the light intensity distribution of an FFP, the divergence angle of the light having the 1/e² intensity of the peak intensity is referred to as the beam divergence angle of the light from the semiconductor laser element. Here, the divergence angle is represented by the angle formed by the light having the peak intensity (light along the optical axis) and the light having the 1/e² intensity of the peak intensity. The beam divergence angle can be obtained, for example, from the light intensity having one half of the peak intensity besides the 1/e² intensity of the peak intensity. In the present specification, when it is simply called the “beam divergence angle,” it refers to the beam divergence angle formed by the light having the 1/e² intensity of the peak intensity.

The fast axis direction divergence angle of the light emitted from a semiconductor laser element can be 15° or larger and smaller than 40°. The slow axis direction divergence angle of the light emitted from the semiconductor laser element can be larger than 0° and 10° at most. The fast axis direction divergence angle of the light is larger than the slow axis direction divergence angle.

For example, the fast axis direction divergence angle of blue light from a semiconductor laser element can be 15° or larger and smaller than 30°, and the slow axis direction divergence angle can be larger than 0° and smaller than 10°. For example, the fast axis direction divergence angle of green light from a semiconductor laser element can be 15° or larger and smaller than 30°, and the slow axis direction divergence angle can be larger than 0° and smaller than 10°. For example, the fast axis direction divergence angle of red light from a semiconductor laser element can be 20° or larger and smaller than 40°, and the slow axis direction divergence angle can be larger than 0° and smaller than 10°.

### Submount 30

A submount 30 has an upper face 31A, a lower face 31B, and one or plural lateral faces 31C. The upper face 31A can be considered as a mounting face on which other constituent elements are mounted. The shape of the upper face 31A is quadrangular. This quadrangular shape of the upper face 31A can have short sides and long sides. The shape of the upper face 31A does not have to be quadrangular.

The outline of a submount 30 in a top view is quadrangular. The quadrangular shape of the outline of the submount 30 can have short sides and long sides. The outline of the submount 30 in a top view does not have to be quadrangular. The submount 30, in a top view, can have an outline in which the length in one direction (hereinafter referred to as the short-length direction) is smaller than the length in the direction perpendicular thereto (hereinafter referred to as the long-length direction). In the submount 30 illustrated, the short-length direction coincides with the X direction and the long-length direction coincides with the Y direction.

A submount 30 can include a substrate 32A and an upper metal member 32B. The submount 30 can further include a lower metal member 32C. The upper metal member 32B is disposed on the upper face side of the substrate 32A. The lower metal member 32B is disposed on the lower face side of the substrate 32A. The submount 30 further has a wiring layer 33. The wiring layer 33 is disposed on the upper metal member 32B.

The substrate 32A has insulation properties. The substrate 32A is formed, for example, with silicon nitride, aluminum nitride, or silicon carbide. A ceramic which dissipates heat relatively well (has high thermal conductivity) can suitably be selected as a primary material for the substrate 32A.

For the primary material for the upper metal member 32B, a metal, such as copper, aluminum, or the like is used. The upper metal member 32B has one or plural metal layers. The upper metal member 32B can have plural metal layers made of different metals as their primary materials.

For the primary material for the lower metal member 32C, a metal, such as copper, aluminum, or the like is used. The lower metal member 32C has one or plural metal layers. The lower metal member 32C can have plural metal layers made of different metals as their primary materials.

The wiring layer 33 can be formed with metal. For example, the wiring layer 33 can be formed by using AuSn solder (AuSn metal layer).

For example, the short side direction or the short-length direction length of a submount 30 is in a range of 500 μm to 1000 μm. The long side direction or the long-length direction length of the submount 30 is in a range of 1500 μm to 2500 μm. The difference between the length in the long-length direction and the length in the short-length direction is in a range of 500 μm to 1000 μm.

For example, the thickness of a submount 30 (the width in the direction perpendicular to the upper face 31A) is in a range of 200 μm to 400 μm. For example, the thickness of the substrate 32A is in a range of 100 μm to 300 μm. For example, the thickness of the upper metal member 32B is in a range of 30 μm to 100 μm. For example, the thickness of the lower metal member 32C is in a range of 30 μm to 100 μm. For example, the thickness of the wiring layer 33 is in a range of 1 μm to 10 μm.

### Reflecting Member 40

A reflecting member 40 has a lower face 41A and a light reflecting face 41B that reflects light. The light reflecting face 41B is oblique to the lower face 41A. The straight line connecting the lower end and the upper end of the light reflecting face 41B is oblique to the lower face 41A. The oblique angle formed by the light reflecting face 41B and the lower face 41A will be referred to as the oblique angle of the light reflecting face 41B.

The light reflecting face 41B is a flat face. The light reflecting face 41B may be a curved face. The oblique angle of the light reflecting face 41B is 45 degrees. The oblique angle of the light reflecting face 41B does not have to be 45 degrees.

For the primary material for the reflecting member 40, glass, metal, or the like can be used. A heat resistant material can be suitably used as the primary material for the reflecting member 40. For the primary material, for example, glass such as quartz or BK7 (borosilicate glass), metals such as Al or the like can be used. The reflecting member 40 can be alternatively formed by using Si as a primary material.

Employing a reflecting material such as Al as the primary material allows the primary material to serve as the light reflecting face 41B. Instead of forming the light reflecting face 41B with the primary material, the reflecting member 40 may be generally shaped with a primary material, and a light reflecting face 41B formed on the surface thereof. In this case, the light reflecting face 41B can be formed by using a metal layer, such as Ag, Al, or the like, or a dielectric multilayer film, such as Ta₂O₅/SiO₂, TiO₂/SiO₂, Nb₂O₅/SiO₂, or the like.

The light reflecting face 41B has a reflectance of 90% or higher for the peak wavelength of the light irradiated on the light reflecting face 41B. The reflectance may be 95% or higher. The reflectance can be set to 99% or higher. The reflectance is 100% or lower, or lower than 100%.

### Protective Element 50

A protective element 50 has an upper face 51A, a lower face 51B, and one or plural lateral faces 51C. The shape of the protective element 50 is a cuboid. The shape of the protective element 50 does not have to be a cuboid.

The protective element 50 is provided for preventing a specific element (e.g., light emitting element) from being destroyed by excess current. One example of protective element 50 is a Zener diode. For the Zener diode, one formed with Si can be employed.

### Wire 60

A wire 60 is a linear conductive material having bonding parts at both ends. The bonding parts at both ends are used to achieve connections with other constituent elements. A wire 60 is, for example, a metal wire. For example, gold, aluminum, silver, copper, or the like can be used as the metal.

### Optical Member 70

An optical member 70 has an upper face 71A, a lower face 71B, and one or plural lateral faces 71C.

The optical member 70 applies an optical action to the light that becomes incident on the optical member 70. The optical actions applied to the light by the optical member 70 include condensing, collimation, dispersion, polarization, diffraction, multiplexing, optical guiding, reflection, wavelength conversion, and the like.

An optical member 70 has an optical action face that applies an optical action. The upper face 71A, the lower face 71B, or a lateral face 71C can be an optical action face. The optical action face may be located at a position other than the upper face 71A, the lower face 71B, and the lateral faces 71C. For example, an optical action face may be formed inside of the optical member 70, rather than on the surface.

An optical member 70 can have one or plural lens faces 71D. A lens face 71D is an optical action face of the optical member 70. An optical member 70 having a lens face 71D may be called a lens member. The light that passes through the lens face 71D and exits the optical member 70 is subjected to an optical action by the optical member 70, such as condensing, dispersion, or collimation. For example, the optical member 70 is a collimating lens which changes the light that became incident on the optical member 70 to collimated light to be output.

The lens face 71D or each lens face 71D is disposed on the upper face 71A side. The lens face 71D may be disposed on the lower face 71B side. The upper face 71A and the lower face 71B are flat faces. The lens face 71D or each lens face 71D intersects the upper face 71A. In a top view, the lens face 71D or each lens face 71D is enclosed by the upper face 71A.

In a top view, the outline of the optical member 70 is quadrangular. The top view outline of the optical member 70 does not have to be quadrangular. The lower face 71B is a flat face. No lens face 71D is formed on the lower face 71B side of the optical member 70. The shape of the lower face 71B is quadrangular. The shape of the lower face 71B does not have to be quadrangular.

In the optical member 70, the portion that overlaps a lens face 71D in a top view is referred to as a lens part 72A. In the optical member 70, the portion that overlaps the upper face 71A in a top view is referred to as the non-lens part 72B. The lower face 71B has a region that constitutes the lower face of the lens part 72A or each lens part 72A and a region that constitutes the lower face of the non-lens part 72B.

An optical member 70 can have plural lens faces 71D that are continuously formed in one direction. In a top view, the direction in which the lens faces 71D are disposed will be referred to as the lens coupling direction. In the optical member 70 illustrated, the coupling direction coincides with the X direction.

The lens faces 71D are formed such that the vertices of the lens faces 71D are positioned on a straight line. The imaginary line connecting the vertices is parallel to the lower face 71B of the optical member 70. The parallel here includes an error of up to ±5 degrees.

Two or more lens faces 71D, which are some or all of the lens faces 71D, can have the same curvature. All of the lens faces 71D can have the same curvature.

An optical member 70 has light transmissivity. The optical member 70 has a transmittance of 80% or higher for the peak wavelength of the light that becomes incident on the optical member 70. The optical member 70 may have a light transmissive region and a region that is not light transmissive (hereinafter referred to as a non-transmissive region). In the non-transmissive region, the transmittance for the peak wavelength of the light incident on the optical member 70 is 50% or lower. The optical member 70 can be formed, for example, by using glass such as BK7.

A light emitting device 1 will be described next.

### Light Emitting Device 1

In a light emitting device 1, plural light emitting elements 20 are disposed in the internal space of a package 10. The light emitting elements 20 are disposed on a substrate 11. The light emitting elements 20 are disposed on the first upper face 11A. The first upper face 11A can be considered as a mounting face on which the light emitting elements 20 are disposed.

The light emitting elements 20 include a first light emitting element 20A, plural second light emitting elements 20B, and plural third light emitting elements 20C. All of the light emitting elements installed in the light emitting device 1 can be composed of a first light emitting element 20A, plural second light emitting elements 20B, and plural third light emitting elements 20C. All of the light emitting elements installed in the light emitting device 1 can be composed of one first light emitting element 20A, two second light emitting elements 20B, and two third light emitting elements 20C.

The first light emitting element 20A, the second light emitting element 20B, and the third light emitting element 20C emit light having different peak wavelengths from one another (e.g., first, second and third peak wavelengths). The first light emitting element 20A, the second light emitting element 20B, and the third light emitting element 20C each emit red, green, or blue light such the colors of light differ from one another. In the example of light emitting device 1 shown in the drawings, the first light emitting element 20A emits blue light, the second light emitting elements 20B emit green light, and the third light emitting elements 20C emit red light.

The light emitting device 1 including plural light emitting elements 20 that emit red light, green light, and blue light can realize an RGB light source without using phosphor excitation techniques. That said, the present specification does not deny the use of phosphor excitation techniques.

As of the time the present application was filed, as far as a semiconductor laser element for use as a light emitting element 20 is concerned, a blue light emitting semiconductor laser element has the highest optical output efficiency. In the case of using an RGB light source for an image display device, such as a projector, it is desirable to increase the optical output in all of RGB colors rather than in one color.

For example, in the case of adding one semiconductor laser element to a light emitting device including four semiconductor laser elements composed of one blue laser element, one green laser element, and two red laser elements, composing the light emitting device including five semiconductor laser elements with one blue laser element, two green laser elements, and two red laser elements can occasionally achieve higher performance (e.g., lumen [lm]) than with one blue laser element, one green laser element, and three red laser elements.

In a light emitting device 1, the number of the second light emitting elements 20B is larger than the number of the first light emitting elements 20A. Moreover, the number of the third light emitting elements 20C is larger than the number of the first light emitting elements 20A. Configuring a light emitting device 1 with multiple light emitting elements 20 in this manner can increase the overall optical output of the light emitting device utilized as an RGB light source, for example. This, in other words, can effectively realize a high output light emitting device 1.

In a top view, the light emitting elements 20 are arranged in one direction. The top view can be considered as a plan view of the mounting face viewed in the direction perpendicular to the mounting face. In the light emitting device 1 illustrated, the first direction coincides with the X direction. The light emitting elements 20 are disposed between the first and second wiring parts 12A1 and 12A2 arranged in one direction and the third and fourth wiring parts 12A3 and 12A4 arranged in one direction.

The light emitting elements 20 are disposed so as to interpose the first light emitting element 20A between the second light emitting elements 20B and the third light emitting elements 20C. This can produce a light emitting device 1 with high manufacturing stability, the details of which will be described later. Among the first light emitting element 20A and the second light emitting elements 20B, those that are more closely located to the first wiring part 12A1 are the second light emitting elements 20B. Among the first light emitting element 20A and the third light emitting elements 20C, those that are more closely located to the fourth wiring part 12A4 are the third light emitting elements 20C.

Each of the light emitting elements 20 emit light in the second direction. The second direction is perpendicular to the first direction. The second direction is parallel to the first upper face 11A. In the light emitting device 1 illustrated, the second direction coincides with the positive Y direction. In the case in which the light emitting elements 20 are semiconductor laser elements, each of the light emitting elements 20 emits light from the light emission face 22 that forms an FFP in which the first direction is the slow axis direction and the direction perpendicular to the first upper face 11A is the fast axis direction.

The light emitting elements 20 are disposed on one or plural submounts 30. The light emitting elements 20 are individually mounted on different submounts 30. One or plural submounts 30 can be composed of plural submounts that include a first submount 30A on which the first light emitting element 20A is mounted, plural second submounts 30B on which the second light emitting elements 20B are individually mounted, and plural third submounts 30C on which the third light emitting elements 20C are individually mounted. Disposing the light emitting elements 20 on the base 11 via the submounts 30 allows the heights of the light emitting elements 20 to be adjusted.

The distance from the first submount 30A to the third submount 30C that is adjacent to the first submount 30A in the first direction is larger than the distance from the first submount 30A to the second submount 30B that is adjacent to the first submount 30A. Furthermore, the second light emitting elements 20B that are semiconductor laser elements are superior to the third light emitting elements 20C that are semiconductor laser elements in terms of temperature characteristics at 45℃. Such a layout of the submounts 30 can contribute to a substantial increase in the output of the light emitting device 1. The 45℃ temperature falls within the general operating temperature range of the light emitting device 1.

The width of a third light emitting element 20C in the first direction is larger than the width of the first light emitting element 20A in the first direction. The first direction width difference between the first submount 30A and a third submount 30C is smaller than the first direction width difference between the first light emitting element 20A and a third light emitting element 20C. The width of a third submount 30C is larger than the width of the first submount 30A in the direction perpendicular to the first direction in a top view. By increasing the number of light emitting elements 20 arranged in the first direction in this manner, and extending the third submounts 30C which are narrow in the first direction in the direction perpendicular to the first direction, well balanced heat dissipation can be achieved. This can contribute to increasing the output of the light emitting device 1.

In a light emitting device 1, light emitting elements 20 include two light emitting elements 20 whose widths in the first direction are different. In the light emitting device 1 illustrated, the first direction width of the first light emitting element 20A differs from that of the third light emitting elements 20C.

The first direction width of the first light emitting element 20 A is smaller than the first direction width of a third light emitting element 20C. The first direction width of a third light emitting element 20C is larger by at least 50 μm or at least 100 μm than the first direction width of the first light emitting element 20A. The first direction width of a third light emitting element 20C can be at least 1.5 times the first direction width of the first light emitting element 20A.

The first direction width difference between the first submount 30A and the first light emitting element 20A is larger than the first direction width difference between a third submount 30C and a third light emitting element 20C. By reducing the first direction margins of the submount 30 for a third light emitting element 20C which is larger in width than the first light emitting element 20A in the first direction, the number of light emitting elements 20 arranged in the first direction can be increased. This can contribute to increasing the output of the light emitting device 1.

In a light emitting device 1, the first light emitting element 20A can be a single emitter semiconductor laser element, and the third light emitting elements 20C can be multi-emitter semiconductor laser elements. The difference in the number of emitters can affect the first direction width difference between light emitting elements 20. A third light emitting element 20C can be a multi-emitter semiconductor laser element having two emitters. A second light emitting elements 20B can be a single emitter semiconductor laser element.

Plural of wires 60 electrically connects the light emitting elements 20 to the base 11. The light emitting elements 20 are electrically connected to the base 11 as wires 60 are bonded to the light emitting elements 20, the submounts 30, or the base 11.

Wires 60 form a first current path which allows an electric current to flow through the first light emitting element 20A. Wires 60 form a second current path which allows an electric current to flow through the second light emitting elements 20B. Wires 60 form a third current path which allows an electric current to flow through the third light emitting elements 20C.

The first current path is taken by the first light emitting element 20A, but not taken by the second light emitting elements 20B and the third light emitting elements 20C. Here, “a light emitting element taking a current path” means that an electric current flowing through the current path flows through and operates the light emitting element, and “a light emitting element not taking a current path” means that an electric current does not flow through or operate the light emitting element even when an electric current flows through the current path.

The second current path is taken by the second light emitting elements 20B, but not taken by any of the first light emitting element 20A and the third light emitting elements 20C. The third current path is taken by the third light emitting elements 20B, but not taken by any of the first light emitting element 20A and the second light emitting elements 20B. Forming the first current path, the second current path, and the third current path allows for independent operation of the first light emitting element 20A, the second light emitting elements 20B, and the third light emitting elements 20C.

One of the two electrodes of each of the first light emitting element 20A, the second light emitting elements 20B, and the third light emitting elements 20C is electrically connected to a common wiring part 12A. This allows the four wiring parts 12A to individually operate the first light emitting element 20A, the second light emitting elements 20B, and the third light emitting elements 20C.

In the light emitting device 1, the first wiring part 12A1 is electrically connected to the first light emitting element 20A at one of the two electrodes of the first light emitting element 20A. The fourth wiring part 12A4 is electrically connected to the first light emitting element 20A at the other of the two electrodes of the first light emitting element 20A. Here, “being electrically connected at one electrode side” or “being electrically connected at the other electrode side” means that, in a current path, the subject is closer to one electrode than the other electrode of the two electrodes is, or the subject is closer to the other electrode than one electrode is.

In the light emitting device 1, the second wiring part 12A2 is electrically connected to the second light emitting elements 20B at one of the two electrodes of at least one of the second light emitting elements 20B. The fourth wiring part 12A4 is electrically connected to the third light emitting elements 20C at the other of the two electrodes of at least one of the second light emitting elements 20B.

In the light emitting device 1, the third wiring part 12A3 is electrically connected to the third light emitting elements 20C at one of the two electrodes of at least one of the third light emitting elements 20C. The fourth wiring part 12A4 is electrically connected to the third light emitting elements 20C at the other of the two electrodes of at least one of the third light emitting elements 20C.

The first current path is formed between the first wiring part 12A1 and the fourth wiring part 12A4. The second current path is formed between the second wiring part 12A2 and the fourth wiring part 12A4. The third current path is formed between the third wiring part 12A3 and the fourth wiring part 12A4. The fourth wiring part 12A4 serves as the common wiring part 12A electrically connected to the other electrode in each of the first light emitting element 20A, the second light emitting elements 20B, and the third light emitting elements 20C.

Wires 60 include a first wire 60A bonded to the first wiring part 12A1. Wires 60 include a second wire 60B bonded to the second wiring part 12A2. Wires 60 include a third wire 60C bonded to the third wiring part 12A3. Wires 60 include a fourth wire 60D bonded to the fourth wiring part 12A4.

A first wire 60A is bonded to the first light emitting element 20A or the first submount 30A. A second wire 60B is bonded to a second light emitting element 20B or a second submount 30B. A third wire 60C is bonded to a third light emitting element 20C or a third submount 30C. A fourth wires 60D is bonded to a submount 30.

In the light emitting device 1, among the first submount 30A and the second submounts 30B, the first submount 30A is closer to the fourth wiring part 12A4. Among the first submount 30A and the third submounts 30C, the third submounts 30C are closer to the fourth wiring part 122A4. A fourth wire 60D is bonded to one of the first submount 30A and the third submount 30C that are adjacent to one another.

In the light emitting device 1, the second direction width difference between the first submount 30A and the first light emitting element 20A is 200 μm or larger. The second direction width difference between a third submount 30C and the third light emitting element 20C is 300 μm or larger. The second direction width difference between a second submount 30B and the second light emitting element 20B is smaller than 100 μm.

Wires 60 include a wire 60 bonded to the fourth wiring part 12A4 and a third submount 30C, a wire 60 bonded to a third submount 30C and the first submount 30A. These wires 60 are both bonded to the submounts 30 at the positions more distant in the opposite direction to the second direction than the lateral faces 21C opposite to the light emission faces 22 of the light emitting elements 20 disposed on the submounts 30 are. Selecting the first submount 30A and the third submounts 30 makes it easier to secure regions of the submounts 30 for bonding the wires 60 in this manner, achieving good bonding stability for the wires 60.

None of the wires 60 that are bonded to the fourth wiring part 12A4 and the third submounts 30C is not bonded to the third submount 30C located closest to the fourth wiring part 12A4. In other words, the other ends of the wires that are bonded to the fourth wiring part 12A4 are bonded to the third submounts 30C other than the third submount 30C that is closest to the fourth wiring part 12A4. This can reduce the number of wires 60 used.

The first submount 30A has two regions, one each at both ends of the first light emitting element 20A in the first direction, for bonding wires 60. The wire 60 bonded to the second submount 30B located next to the first submount 30A is bonded in one of these two regions that is secured on the second light emitting element 20B side with respect to the first light emitting element 20A. The wire 60 bonded to the third submount 30C located next to the first submount 30A is bonded in one of the two regions secured on the third light emitting element 20C side with respect to the first light emitting element 20A. The position of the first light emitting element 20A is adjusted so as to secure the region for bonding the wires 60 as described above.

A region for bonding a wire 60 is secured in a third submount 30C at a location that is distant in the opposite direction to the second direction than the third light emitting element 20C is. A wire 60 for connection with the first submount 30A located next to the third submount 30C is bonded in this region of the third submount 30C adjacent to the first submount 30A. In this region, a wire 60 for connection with the fourth wiring part 12A4 is bonded. In this third mount 30C, a region for bonding a wire 60 is secured only on one side, not both sides, of the third light emitting element 20C in the first direction. This can reduce the first direction width of the third submount 30C, which can increase the number of light emitting elements 20 arranged in the first direction, thereby producing a high output light emitting device 1.

One or more wires 60 are bonded in the region of the upper face 31A of the first submount 30A located between the imaginary plane that includes the light emission face 22 of the first light emitting element 20A and the imaginary plane that includes the lateral face 21C opposite to the light emission face 22. No wire 60 is present in the region of the upper face 31A of a third submount 30C located between the imaginary plane that includes the light emission face 22 of the third light emitting element 20C and the imaginary plane that includes the lateral face 21C opposite to the light emission face 22.

By adjusting the first direction widths of the submounts 30 for increasing output, not disposing any wire 60 on the third submount 30C at a position distant from the third light emitting element 20C in the first direction, and disposing a wire 60 at a position that is distant from at last the third light emitting element 20C in the opposite direction to the second direction, the possibility of contacting the third light emitting element 20C can be reduced and the wires 60 can be bonded in a stable manner.

In the light emitting device 1, the shape of the wiring layer 33 of the first submount 30A is the same as the shape of the wiring layer 33 of a second submount 30B in a top view. Furthermore, the outline of the first submount 30A is the same as the outline of a second submount 30B in a top view. In the light emitting device 1, the first submount 30A and the second submounts 30B are the same in terms of the material, the shape, and the structure. Designing a wiring layer 33 and the like so as to allow the same submounts 30 to be used for mounting the first light emitting element 20A and the second light emitting elements 20B in this manner can increase the production efficiency for the light emitting device 1.

In the light emitting device 1, the second wiring part 12A2 is positioned to be distant from the first wiring part 12A1 in the second direction. This can facilitate the bonding process for the wires 60 bonded to the first light emitting element 20A or the first submount 30A while avoiding interference with the wires 60 that are bonded to the second light emitting elements 20B and the second submounts 30B.

In the light emitting device 1, the third wiring part 12A3 is positioned to be distant from the fourth wiring part 12A4 in the second direction. This can facilitate the bonding process for the wires 60 bonded to the first light emitting element 20A or the first submount 30A while avoiding interference with the wires 60 that are bonded to the third light emitting elements 20C and the third submounts 30C.

In a top view, the distance from the center of a second submount 30B to the second wiring part 12A2 is shorter than the distance from the center thereof to the first wiring part 12A1. This can facilitate the bonding process for the second wires 60B. In a top view, the distance from the center of a third submount 30C to the third wiring part 12A3 is shorter than the distance from the center thereof to the fourth wiring part 12A4. This can facilitate the bonding process for the third wires 60C.

In arranging plural light emitting elements 20 including a first light emitting element 20A, plural second light emitting elements 20B, and plural third light emitting elements 20C on a base 11 and electrically connecting the light emitting elements 20 to the base 11, positioning the first light emitting element 20A between the second light emitting elements 20B and the third light emitting elements 20C can achieve a light emitting device 1 with high manufacturing stability, for example, a manner ensuring bonding stability in bonding multiple wires 60. This will be described in detail below.

FIGS. 14A and 14B show an example of how wiring connections are made when plural second light emitting elements 20B are disposed between a first light emitting element 20A and plural third light emitting elements 20C. In a light emitting device 99 having such wiring connections, in order to form a current path that is taken by the first light emitting element 20A and not taken by the second light emitting elements 20B and the third light emitting elements 20C, there must be a wire 60X that is bonded to two submounts 30 that interpose one or more submounts 30. In contrast, a light emitting device 1 which has no wire 60 that is bonded to two submounts 30 that interpose one or more submounts 30 ensures high bonding stability.

Furthermore, the wire 60X passing directly over the two submounts 30 (the second submounts 30B in FIG. 14A) applies restrictions on the regions for bonding wires 60 in order to avoid contact with the wire 60X. This requires a wire 60Y that is located close to other wires 60. Wires 60 being too close to one another in a top view require a measure for eliminating risks of contact such as providing adequate height differences when bonding wires 60. The risks of contact with other constituent elements such as a lid 14 is relatively higher for the light emitting device 99 than the light emitting device 1, adversely affecting the mounting stability. This can otherwise increase the size of the light emitting device. In other words, a light emitting device 1 can facilitate the size reduction of the light emitting device.

Moreover, the wire 60Z bonded to the adjacent submount 30 can also be bonded to the submount 30 to which the wire 60X is bonded (the first submount 30A in FIG. 14A). The region for bonding the wire 60Z is also restricted in order to avoid contact with the wire 60X. In the case of bonding multiple wires 60 to the upper face 21A of a semiconductor laser element which is a light emitting element 20, it is preferable to bond the wires 60 at equal intervals in the resonator direction (the Y direction in the drawing) considering the current distribution. The bonding position of the wire 60 closest to the light emission face 22 is not preferably too far from the light emission face 22. In the case of the form of the wiring connections shown in FIG. 14B, the wire 60Z is positioned close to the wire 60X in a top view, which makes the contact risk relatively higher for the light emitting device 99 than the light emitting device 1 to thereby adversely affect the mounting stability. Alternatively, this may increase the size of the light emitting device. In other words, the light emitting device 1 can facilitate the size reduction of the light emitting device.

In a light emitting device 1, three or more wires 60 are bonded to the light emitting elements 20. Three or more wires 60 can be bonded to each light emitting element 20, but three or more wires 60 do not have to be bonded to all of the light emitting elements 20 because of the differences in the performance and the characteristics among the light emitting elements 20.

In a light emitting device 1, one or plural reflecting members 40 are disposed in the internal space of the package 10. The one or plural reflecting members 40 are disposed on the base 11. The one or plural reflecting members 40 are disposed on the upper face 1A. The one or plural reflecting members 40 are positioned to be distant from the light emitting elements 20 in the second direction.

The one or plural reflecting members 40 reflect the light emitted by the light emitting elements 20. The one or plural light reflecting faces 41B reflect the light emitted from the light emission faces 22 of the light emitting elements 20. The light reflected by the one or plural reflecting members 40 travels upwards. The light reflected by the one or plural reflecting members 40 passes through the lid 14 and exits the upper face 14A.

In a light emitting device 1, one or plural protective elements 50 are disposed in the internal space of the package 10. The one or plural protective elements 50 are bonded to the base 11 or a submount 30. The one or plural protective elements 50 are provided to protect the light emitting elements 20.

In a light emitting device 1, an optical member 70 is fixed to the package 10. The optical member 70 is positioned such that the light from the light emitting elements 20 hits an optical action face. The optical member 70 is bonded to the package 10 via an adhesive. The optical member 70 applies an optical action to the light that hits the optical action face before the light exits the optical member 70. In the light emitting device 1 illustrated, the lights emitted by plural light emitting elements 20 pass through plural lens faces 71D. The light that passed through a lens face 71D is collimated light when it is output from the optical member 70.

### Second Embodiment

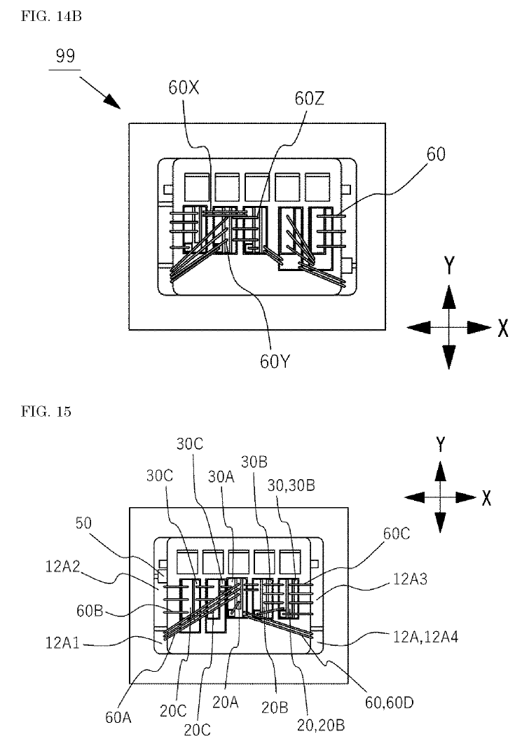

A light emitting device 2 according to a second embodiment will be explained. FIGS. 1 to 3, FIGS. 7 to 13, and FIG. 15 are drawings explaining an exemplary form of light emitting device 2. FIG. 1 is a perspective view of a light emitting device 2. FIG. 2 is a top view of the light emitting device 2. FIG. 3 is a cross-sectional view of the light emitting device 2 taken along line III-III in FIG. 2. FIG. 7 is a top view of a package 10. FIG. 8 is a cross-sectional view of the package 10 taken along line VIII-VIII in FIG. 7. FIG. 9 is a cross-sectional view of a base 11 corresponding to the cross-sectional view of the package 10 in FIG. 8. FIG. 10 is a top view of the base 11. FIG. 11 is a bottom view of the base 11. FIG. 12 is a top view showing a submount 30 on which a light emitting element 20 and a protective element 50 are mounted. FIG. 13 is a side view showing the submount 30 on which the light emitting element 20 and the protective element 50 are mounted. FIG. 15 is a top view showing a wiring connection form of the wire 60 in a light emitting device 2 according to the second embodiment.

The description of the light emitting device 1 and the constituent elements according to the first embodiment provided above except for the content considered inconsistent with FIGS. 1 to 3, 7 to 13 and 15 in relation to the light emitting device 2 can also apply to the light emitting device 2. The description that is consistent will not be repeated here to avoid redundancy.

### Light Emitting Device 2

A light emitting device 2 is an example in which the positions of the second light emitting elements 20B and the third light emitting elements 20C are reversed from the arrangement in the light emitting device 1. In the light emitting device 2, plural third light emitting elements 20C are disposed between the first light emitting element 20A and the first and second wiring parts 12A1 and 12A2 in a top view, and plural second light emitting elements 20B are disposed between the first light emitting element 20A and the third and fourth wiring parts 12A3 and 12A4. Although there are some differences from the light emitting device 1 in terms of how the wires 60 are connected, such an arrangement of the light emitting elements 20 can also achieve a high output light emitting device with high manufacturing stability in a manner similar to the light emitting device 1.

In the light emitting device 2, the fourth wire 60D is bonded to the fourth wiring part 12A4 and the first submount 30A. Connecting the fourth wiring part 12A4 and the first submount 30A using a single wire 60 can reduce the number of wires 60.

### Third Embodiment

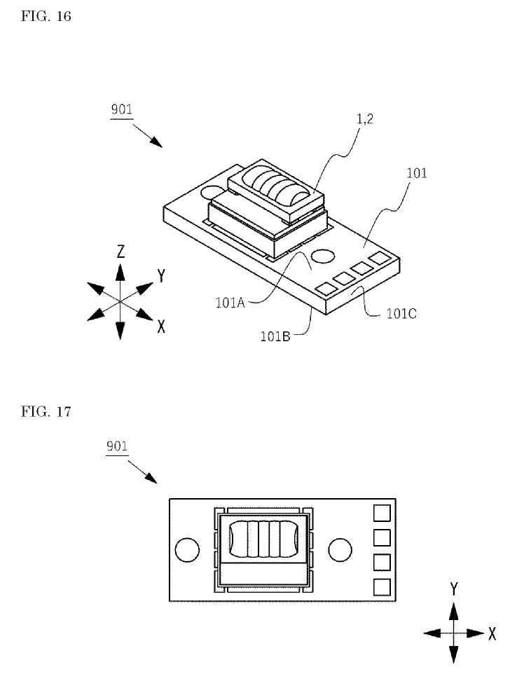

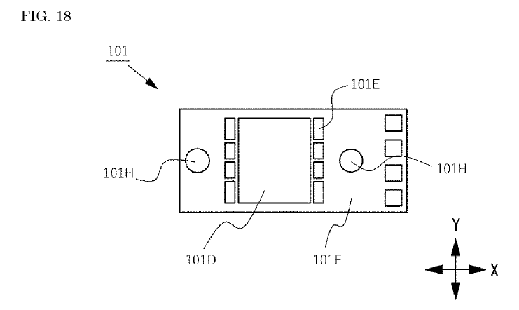

A light emitting module 901 according to a third embodiment will be explained. FIGS. 1 to 13 and 15 to 18 are drawings explaining an exemplary form of a light emitting module 901. FIGS. 1 to 13 and 15 are drawings explaining a light emitting device included in the light emitting module 901. FIG. 16 is a perspective view of the light emitting module 901. FIG. 17 is a top view of the light emitting module 901. FIG. 18 is a top view of a wiring board 101.

A light emitting module 901 includes a plurality of constituent elements. The constituent elements of the light emitting module 901 include a light emitting device and a wiring board 101. The light emitting module 901 may include other constituent elements. For example, the light emitting module 901 may include a temperature measuring element such as a thermistor.

For the light emitting device included in the light emitting module 901, a light emitting device 1 according to the first embodiment or a light emitting device 2 according to the second embodiment can be employed. The description of the first embodiment and the second embodiment applies to the light emitting device 1 or 2 included in the light emitting module 901.

### Wiring Board 101

A wiring board 101 has an upper face 101A, a lower face 101B, and one or plural lateral faces 101C. The wiring board 101 has a sheet shape. In a top view, the outline of the wiring board 101 is quadrangular. This quadrangular shape can have long sides and short sides. In the package 10 illustrated, the short side direction of the quadrangular shape coincides with the X direction and the long side direction coincides with the Y direction.

The wiring board 101 has a heat dissipating part 101D, an electrode part 101E, and an insulation part 101F. The heat dissipating part 101D functions as the heat dissipating path for the heat generated by other constituent elements mounted on the wiring board 101. The electrode part 101E is electrically connected to other constituent elements mounted on the wiring board 101.

The insulation part 101F isolates the heat dissipating part 101D from the electrode part 101E. The insulation part 101F is provided to electrically isolate the heat dissipating part 101D from the electrode part 101E in the wiring board 101.

The wiring board 101 has one or plural through holes 101H. The one or plural through holes 101H include a through hole 101H for fixing another member (constituent element) to the wiring board 101. For example, a screw is fitted in a through hole 101H to fix the wiring board 101 to another member. The one or plural through holes 101H include a through hole 101H that is used for positioning the wiring board 101 when being fixed to another member.

### Light Emitting Module 901

In a light emitting module 901, a light emitting device 1 or 2 is mounted on the wiring board 101. The light emitting device 1 or 2 is mounted on the upper face 101A of the wiring board 101. The light emitting device 1 or 2 is electrically connected to the wiring board 101 as the wiring parts 12A disposed on the lower face 11B of the light emitting device 1 or 2 are joined to the electrode part 101E of the wiring board 101.

The light emitting device 1 or 2 is disposed on the wiring board 101 so as to align the long side direction of the package 10 with the long side direction of the wiring board 101 in a top view. This can produce a small light emitting module 901. A small light emitting module 901 can produce, for example, a small projector.

The light emitting device 1 or 2 can be a single light emitting device that emits light of three colors of red, green, and blue, for example. For example, the first light emitting element 20A is a blue light emitting semiconductor laser element, the second light emitting elements 20B are red or green light emitting semiconductor laser elements, and the third light emitting elements 20C are semiconductor laser elements that emit red or green light that is the color different from that emitted by the second light emitting elements 20B.

As described above, the light emitting module 901 can serve as an RGB light source by itself, and can particularly be suited for a compact RGB light source projector such as a pico projector.

Particularly, the light emitting module 901 whose output is substantially enhanced by employing, for the light emitting elements 20, semiconductor laser elements that generally have higher outputs than light emitting diodes (LEDs) while increasing the numbers of green light emitting elements 20 and red light emitting elements 20 compared to the number of blue light emitting elements 20 can greatly contribute to realizing an ideal pico projector that is compact, has high output, and saves energy.

Such a light emitting module 901 can be installed in a projector that employs an RGB light source as a light source and having an optical output [lm] of 350 lm or higher. With such a light emitting module 901, a projector equipped only with a single light emitting module 901 as a light source and having an optical output [lm] in a range of 350 lm to 600 lm can be realized.

In the foregoing, certain embodiments of the present disclosure have been explained. The light emitting devices and light emitting modules according to present disclosure, however, are not strictly limited to those disclosed in the embodiments. In other words, the present disclosure is implementable without limiting the outer shape or the structure of a light emitting device or a light emitting module to those disclosed by the embodiments. Furthermore, it is not essential for the applicability of the present disclosure to include all of the constituent elements necessarily and fully. For example, in the event that a certain constituent element of a light emitting device disclosed by any of the embodiments is not disclosed in the claim scope, we claim the applicability of the disclosure disclosed in the claim scope by recognizing the design flexibility for a person of ordinary skill in the art for such a constituent element through the use of an alternative, an omission, a shape change, a change in the materials employed, or the like.

The light emitting devices and the light emitting modules disclosed in any of the embodiments can be used in a projector. In other words, a projector is one form of usage to which the present disclosure can be applied. Not limited to this, the present disclosure can be utilized in various forms of usage, such as lighting fixtures, exposure devices, automotive headlights, head-mounted displays, backlights for other displays, and the like.

What is claimed is:

1. A light emitting device comprising:
a plurality of light emitting elements including a first light emitting element, a plurality of second light emitting elements, and a plurality of third light emitting elements, each of the plurality of light emitting elements including two electrodes that are an anode electrode and a cathode electrode;
a base including a first wiring part, a second wiring part, a third wiring part, a fourth wiring part, and a mounting face provided between two of the first wiring part, the second wiring part, the third wiring part, and the fourth wiring part in a plan view; and
a plurality of wires electrically connecting the plurality of light emitting elements to the base, wherein
in the plan view, the plurality of light emitting elements are disposed on the mounting face with the first light emitting element being arranged between the plurality of second light emitting elements and the plurality of third light emitting elements,
the first wiring part is electrically connected to the first light emitting element at one of the two electrodes,
the second wiring part is electrically connected to the plurality of second light emitting elements at one of the two electrodes,
the third wiring part is electrically connected to the plurality of third light emitting elements at one of the two electrodes,
the fourth wiring part is electrically connected to the first light emitting element at the other of the two electrodes, each of the plurality of second light emitting elements at the other of the two electrodes, and each of the plurality of third light emitting elements at the other of the two electrodes,
a first current path is formed between the first wiring part and the fourth wiring part to be taken by the first light emitting element and not taken by any of the plurality of second light emitting elements and the plurality of third light emitting elements,
a second current path is formed between the second wiring part and the fourth wiring part to be taken by the plurality of second light emitting elements and not taken by any of the first light emitting element and the plurality of third light emitting elements, and
a third current path is formed between the third wiring part and the fourth wiring part to be taken by the plurality of third light emitting elements and not taken by any of the first light emitting element and the plurality of second light emitting elements.

2. The light emitting device according to claim 1, wherein
the first light emitting element is configured to emit light having a first peak wavelength,
the plurality of second light emitting elements are configured to emit light having a second peak wavelength different from the first peak wavelength, and
the plurality of third light emitting elements are configured to emit light having a third peak wavelengths different from the first peak wavelength and the second peak wavelength.

3. The light emitting device according to claim 1, wherein
the first light emitting element is configured to emit light of a color that is one of red, green, and blue,
the plurality of second light emitting elements are configured to emit light of a color that is of one of red, green, and blue, and that is different from the color of the light emitted by the first light emitting element, and
the plurality of third light emitting elements are configured to emit light of a color that is one of red, green, and blue, and that is different from the colors of the lights emitted by the first light emitting element and the plurality of second light emitting elements.

4. The light emitting device according to claim 1, wherein all of the plurality of light emitting elements are semiconductor laser elements.

5. The light emitting device according to claim 1, further comprising a plurality of submounts each including a wiring layer, the plurality of submounts including a first submount on which the first light emitting element is disposed, a plurality of second submounts on which the plurality of second light emitting elements are respectively and individually disposed, and a plurality of third submounts on which the plurality of third light emitting elements are respectively and individually disposed.

6. The light emitting device according to claim 5, wherein a shape of the wiring layer of the first submount and a shape of the wiring layer of each of the second submounts are the same in the plan view.

7. The light emitting device according to claim 5, wherein
the wires include
a first wire bonded to the first wiring part and the first light emitting element or the first submount;
a second wire bonded to the second wiring part and one of the second light emitting elements or one of the second submounts,
a third wire bonded to the third wiring part and one of the third light emitting elements or one of the third submounts, and
a fourth wire bonded to the fourth wiring part and one of the submounts.

8. The light emitting device according to claim 5, wherein
the plurality of light emitting elements are aligned along a first direction in the plan view,
a first direction width of the first light emitting element is smaller than a first direction width of one of the plurality of third light emitting elements, and
a first direction width difference between the first submount and one of the plurality of third submounts is smaller than a first direction width difference between the first light emitting element and one of the plurality of third light emitting elements.

9. The light emitting device according to claim 1, wherein
in the plan view,
the light emitting elements are aligned along a first direction,
the first wiring part and the second wiring part are aligned along a second direction that is perpendicular to the first direction,
the third wiring part and the fourth wiring part are aligned along the second direction, and
the first wiring part and the second wiring part are arranged on one side of the light emitting elements and the third wiring part and the fourth wiring part are arranged on the other side of the light emitting elements with respect to the first direction.

10. The light emitting device according to claim 9, wherein the second wiring part is spaced apart from the first wiring part in the second direction, and the third wiring part is spaced apart from the fourth wiring part in the second direction.

11. The light emitting device according to claim 10, wherein each of the light emitting elements is configured to emit light in the second direction.

12. A light emitting module comprising:
the light emitting device according to claim 1; and
a wiring board on which the light emitting device is mounted.

13. The light emitting module according to claim 12, wherein
the first light emitting element is a semiconductor laser element configured to emit blue light,
the plurality of second light emitting elements are semiconductor laser elements configured to emit red or green light, and
the plurality of third light emitting elements are semiconductor laser elements configured to emit red or green light that is a color light different from that emitted by the plurality of second light emitting elements.

14. A projector comprising:
an RGB light source including the light emitting module according to claim 13, the RGB light source having an optical output of 350 lm or higher.
